(19) United States
(12) Patent Application Publication
(10) Pub. No.: US 2020/0211911 A1
(43) Pub. Date: Jul. 2, 2020

(54) SPACER-PATTERNED INVERTERS BASED ON THIN-FILM TRANSISTORS

(71) Applicant: Intel Corporation, Santa Clara, CA (US)

(72) Inventors: Abhishek A. SHARMA, Hillsboro, OR (US); Van H. LE, Beaverton, OR (US); Gilbert DEWEY, Hillsboro, OR (US); Willy RACHMADY, Beaverton, OR (US)

(21) Appl. No.: 16/637,932

(22) PCT Filed: Sep. 29, 2017
(86) PCT No.: PCT/US17/54413

§ 371 Date: Feb. 10, 2020

(51) Int. Cl. H01L 21/84; H01L 27/12

(52) U.S. Cl. CPC H01L 21/845; H01L 27/1207; H01L 27/1225; H01L 27/127; H01L 27/1211

(57) ABSTRACT

A semiconductor device may include a first gate electrode and a second gate electrode. A first channel area and a second channel area may be above the first gate electrode, where the first channel area may include a first type channel material, and the second channel area may include a second type channel material. A third channel area and a fourth channel area may be above the second gate electrode, where the third channel area may include the first type channel material, and the fourth channel area may include the second type channel material. The third channel area may be separated from the first channel area by a spacer. An inverter may include the first gate electrode, the first channel area, and the second channel area, while another inverter may include the second gate electrode, the third channel area, and the fourth channel area. Other embodiments may be described/claimed.

### FIELD

Embodiments of the present disclosure generally relate to the field of integrated circuits, and more particularly, to inverters and thin-film transistors.

### BACKGROUND

A conventional transistor may have a channel within a substrate, such as a silicon substrate. A conventional transistor may be fabricated at the front-end-of-line (FEOL) by lithography techniques based on various patterns. A thin-film transistor (TFT) is a kind of field-effect transistor including a channel layer, a gate electrode, and source and drain electrodes, over a supporting but non-conducting substrate. TFTs have emerged as an attractive option to fuel Moore's law by integrating TFTs vertically in the back-end-of-line (BEOL), while leaving the silicon substrate areas for high-speed transistors. TFTs hold great potential for large area and flexible electronics, e.g., displays. Other applications of TFTs may include memory arrays. However, current techniques may be limited to patterning and fabrication of TFTs at the BEOL. Techniques for integrating larger device, e.g., inverters, at the BEOL may further benefit the semiconductor industry.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 illustrates schematic diagrams and cross section diagrams of a semiconductor device including two inverters formed at the back-end-of-line (BEOL) above a substrate and multiple gate electrodes, in accordance with some embodiments.

FIG. 2 illustrates a process for forming a semiconductor device including two inverters at the BEOL above a substrate and multiple gate electrodes, in accordance with some embodiments.

FIGS. 3-10 illustrate various stages of a process for forming a semiconductor device including two inverters at the BEOL above a substrate and multiple gate electrodes, in accordance with some embodiments.

FIG. 11 schematically illustrates a diagram of a semiconductor device including two inverters at the BEOL above a substrate and multiple gate electrodes, in accordance with some embodiments.

FIG. 12 schematically illustrates an interposer implementing one or more embodiments of the disclosure, in accordance with some embodiments.

FIG. 13 schematically illustrates a computing device built in accordance with an embodiment of the disclosure, in accordance with some embodiments.

### DETAILED DESCRIPTION

Thin-film transistors (TFTs) may be useful for many applications, e.g., large area displays, memory arrays, and other applications. TFTs may be fabricated at the back-end-of-line (BEOL). In addition, techniques for integrating larger device, e.g., inverters, at the BEOL may further benefit the semiconductor industry.

Embodiments herein may present a semiconductor device, which may include a substrate, and a first gate electrode and a second gate electrode above the substrate. The first gate electrode and the second gate electrode may be separated by a spacer. A first channel area and a second channel area may be above the first gate electrode, where the first channel area may include a first type channel material, and the second channel area may include a second type channel material. A third channel area and a fourth channel area may be above the second gate electrode, where the third channel area may include the first type channel material, and the fourth channel area may include the second type channel material. The third channel area may be separated from the first channel area by the spacer. A first source-drain contact may be coupled to a source area of the first channel area and a drain area of the second channel area. A second source-drain contact may be coupled to a source area of the third channel area and a drain area of the fourth channel area. A drain contact may be coupled to a drain area of the first channel area, a source contact may be coupled to a source area of the second channel area, a drain contact may be coupled to a drain area of the third channel area, and a source contact may be coupled to a source area of the fourth channel area.

Embodiments herein may present a computing device, which may include a processor, and a memory device coupled to the processor. The processor or the memory device may include a first inverter and a second inverter. The first inverter and the second inverter may include a substrate, a first gate electrode and a second gate electrode above the substrate, where the first gate electrode and the second gate electrode may be separated by a spacer. A first channel area and a second channel area may be above the first gate electrode, where the first channel area may include a first type channel material, and the second channel area may include a second type channel material. A third channel area and a fourth channel area may be above the second gate electrode, where the third channel area may include the first type channel material, and the fourth channel area may include the second type channel material. The third channel area may be separated from the first channel area by the spacer. A first source-drain contact may be coupled to a source area of the first channel area and a drain area of the second channel area, a second source-drain contact may be coupled to a source area of the third channel area and a drain area of the fourth channel area. The first inverter may include the first gate electrode, the first channel area, the second channel area, and the first source-drain contact coupled to the source area of the first channel area and the drain area of the second channel area. The second inverter may include the second gate electrode, the third channel area, the fourth channel area, and the second source-drain contact coupled to the source area of the third channel area and the drain area of the fourth channel area.

In embodiments, a method for forming a semiconductor device may include: forming a backbone area above a gate electrode, where the gate electrode may be above a substrate; forming a continuous fin of a first type conformally covering the backbone area, where the continuous fin of the first type may include a first type channel material; forming an oxide area conformally covering the continuous fin of the first type; forming a continuous fin of a second type conformally covering the oxide area, where the continuous fin of the second type may include a second type channel material. The method may further include removing a top part of the continuous fin of the second type, a top part of the oxide area, a top part of the continuous fin of the first type, to expose the backbone. The continuous fin of the first type may become a first fin of the first type and a second fin of the first type disconnected from each other, and the continuous fin of the second type may become a first fin of the second type and a second fin of the second type disconnected from each other. The method may further include removing the backbone area and a part of the gate electrode to have a gap, where the gate electrode may become a first gate electrode and a second gate electrode disconnected from each other; and filling the gap by a dielectric material to form a spacer.

In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure. However, the order of description should not be construed to imply that these operations are necessarily order dependent. In particular, these operations may not be performed in the order of presentation.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

As used herein, the term “circuitry” may refer to, be part of, or include an Application Specific Integrated Circuit (ASIC), an electronic circuit, a processor (shared, dedicated, or group), and/or memory (shared, dedicated, or group) that execute one or more software or firmware programs, a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

Implementations of the disclosure may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present disclosure.

A plurality of transistors, such as metal-oxide-semiconductor field-effect transistors (MOSFET or simply MOS transistors), may be fabricated on the substrate. In various implementations of the disclosure, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the disclosure may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type work function metal or N-type work function metal, depending on whether the transistor is to be a PMOS or an NMOS transistor. In some implementations, the gate electrode layer may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a work function that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a work function that is between about 3.9 eV and about 4.2 eV.

In some implementations, when viewed as a cross-section of the transistor along the source-channel-drain direction, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the disclosure, the gate electrode may consist of a combination of U-shaped structures and planar, non-U-shaped structures. For example, the gate electrode may consist of one or more U-shaped metal layers formed atop one or more planar, non-U-shaped layers.

In some implementations of the disclosure, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process operations. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (Sift), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

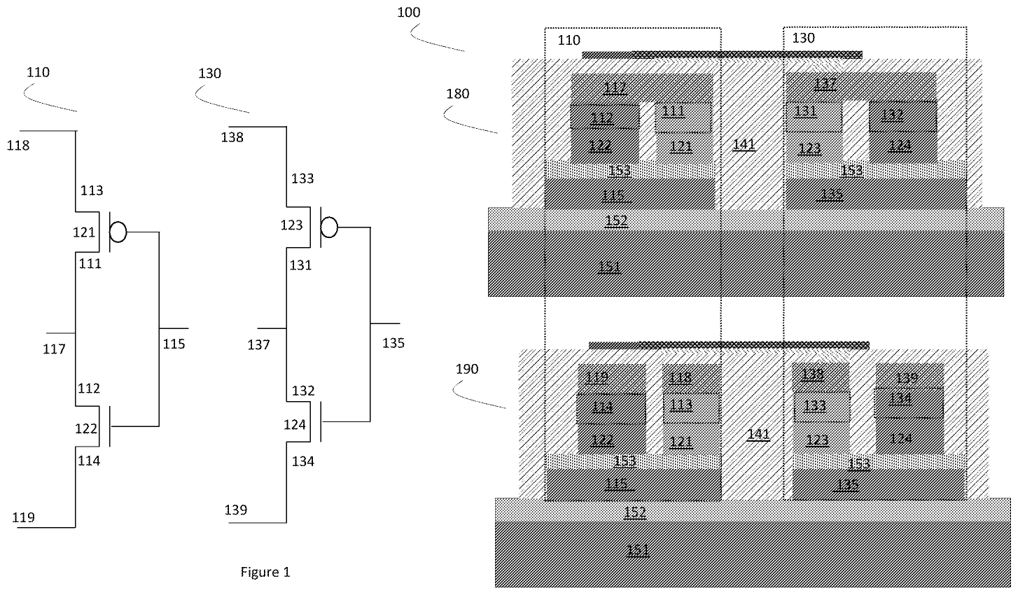

FIG. 1 illustrates schematic diagrams and cross section diagrams of a semiconductor device 100 including two inverters, e.g., an inverter 110 and an inverter 130, formed at the BEOL above a substrate 151 and multiple gate electrodes, e.g., a gate electrode 115 and a gate electrode 135, in accordance with some embodiments. For clarity, features of the inverter 110 and the inverter 130, the substrate 151, the gate electrode 115, and the gate electrode 135, may be described below as examples for understanding an example inverters, a substrate, and/or gate electrodes. It is to be understood that there may be more or fewer components within inverters, a substrate, and/or gate electrodes. Further, it is to be understood that one or more of the components within inverters, a substrate, and/or gate electrodes, may include additional and/or varying features from the description below, and may include any device that one having ordinary skill in the art would consider and/or refer to as inverters, a substrate, and/or gate electrodes.

The semiconductor device 100 may be illustrated by a cross section diagram 180 and a cross section diagram 190, taking from different sections of the three-dimensional semiconductor device 100 including the inverter 110 and the inverter 130. In addition, the inverter 110 and the inverter 130 may be illustrated by schematic diagrams.

In embodiments, the semiconductor device 100 may include the substrate 151, and an ILD layer 152 above the substrate 151. The gate electrode 115 and the gate electrode 135 may be above the ILD layer 152 and the substrate 151, where the gate electrode 115 and the gate electrode 135 may be separated by a spacer 141. A gate dielectric layer 153 may be above the gate electrode 115 and the gate electrode 135.

A first channel area 121 and a second channel area 122 may be above the gate electrode 115 and the gate dielectric layer 153, where the first channel area 121 may include a first type channel material, and the second channel area 122 may include a second type channel material.

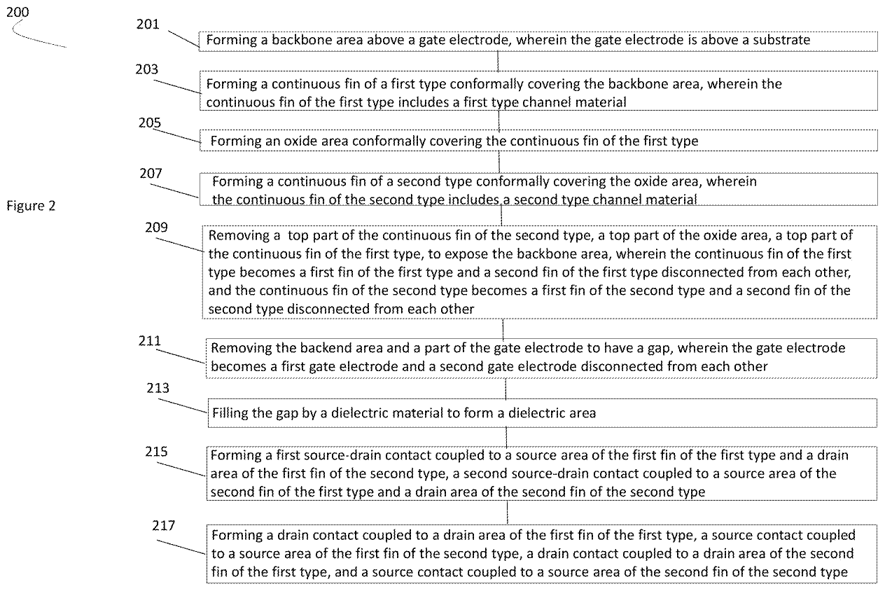

The first type channel material may be an n-type channel material, while the second type channel material may be a p-type channel material. Additionally and alternatively, the first type channel material may be a p-type channel material, while the second type channel material may be an n-type channel material. A third channel area 123 and a fourth channel area 124 may be above the gate electrode 135 and the gate dielectric layer 153, where the third channel area 123 may include the first type channel material, and the fourth channel area 124 may include the second type channel material. The third channel area 123 and the first channel area 121 may be adjacent to each other, but not in physical contact. In embodiments, the third channel area 123 and the first channel area 121 may be patterned at a same time, or by a same operation, as shown in FIG. 2. Similarly, the fourth channel area 124 and the second channel area 122 may be patterned at a same time, or by a same operation, as shown in FIG. 2. The third channel area 123 may be separated from the first channel area 121 by the spacer 141.

As shown in the cross section diagram 180, a first source-drain contact 117 may be coupled to a source area 111 of the first channel area 121 and a drain area 112 of the second channel area 122. A second source-drain contact 137 may be coupled to a source area 131 of the third channel area 123 and a drain area 132 of the fourth channel area 124. As shown in the cross section diagram 190, a drain contact 118 may be coupled to a drain area 113 of the first channel area 121, a source contact 119 may be coupled to a source area 114 of the second channel area 122. A drain contact 138 may be coupled to a drain area 133 of the third channel area 123, and a source contact 139 may be coupled to a source area 134 of the fourth channel area 124. In embodiments, a source and a drain may be used interchangeably.

As shown in the schematic diagram, together with the cross section diagram 180 and the cross section diagram 190, the inverter 110 may include the gate electrode 115, the first channel area 121, the second channel area 122, and the first source-drain contact 117 coupled to the source area 111 of the first channel area 121 and the drain area 112 of the second channel area 122. The inverter 110 may further include the drain contact 118 coupled to the drain area 113 of the first channel area 121, and the source contact 119 coupled to the source area 114 of the second channel area 122.

As shown in the schematic diagram, together with the cross section diagram 180 and the cross section diagram 190, the inverter 130 may include the gate electrode 135, the third channel area 123, the fourth channel area 124, and the second source-drain contact 137 coupled to the source area 131 of the third channel area 123 and the drain area 132 of the fourth channel area 124. The inverter 130 may further include the drain contact 138 coupled to the drain area 133 of the third channel area 123 and the source contact 139 coupled to the source area 134 of the fourth channel area 124.

In embodiments, the substrate 151 may be a silicon substrate, a glass substrate, such as soda lime glass or borosilicate glass, a metal substrate, a plastic substrate, or another suitable substrate. Other dielectric layer or other devices may be formed on the substrate 151, not shown for clarity.

In embodiments, the ILD layer 152, or the spacer 141, may include a silicon oxide (SiO) film, a silicon nitride (SiN) film, O₃-tetraethylorthosilicate (TEOS), O₃-hexamethyldisiloxane (HMDS), plasma-TEOS oxide layer, or other suitable materials. In embodiments, the spacer 141 may separate the first channel area 121 and the third channel area 123 that may include a same first type channel material.

In embodiments, the gate dielectric layer 153 may include silicon and oxygen, silicon and nitrogen, yttrium and oxygen, silicon, oxygen, and nitrogen, aluminum and oxygen, hafnium and oxygen, tantalum and oxygen, or titanium and oxygen. For example, the gate dielectric layer 153 may include silicon oxide (Sift), silicon nitride (SiNₓ), yttrium oxide (Y₂O₃), silicon oxynitride (SiOₓNO_{y}), aluminum oxide (Al₂O₃), hafnium (IV) oxide (HfO₂), tantalum oxide (Ta₂O₅), titanium dioxide (TiO₂), or other materials.

In embodiments, the gate electrode 115, the gate electrode 135, the first source-drain contact 117, the second source-drain contact 137, the drain contact 118, the source contact 119, the drain contact 138, or the source contact 139, may be formed as a single layer or a stacked layer using one or more conductive films including a conductive material. For example, the gate electrode 115, the gate electrode 135, the first source-drain contact 117, the second source-drain contact 137, the drain contact 118, the source contact 119, the drain contact 138, or the source contact 139, may include gold (Au), platinum (Pt), ruthenium (Ru), iridium (Ir), titanium (Ti), aluminum (Al), molybdenum (Mo), gold (Au), copper (Cu), tantalum (Ta), tungsten (W), nickel (Ni), chromium (Cr), or an alloy of Ti, Mo, Au, Pt, Al Ni, Cu, Cr, TiAlN, HfAlN, or InAlO. For example, the gate electrode 115, the gate electrode 135, the first source-drain contact 117, the second source-drain contact 137, the drain contact 118, the source contact 119, the drain contact 138, or the source contact 139, may include tantalum nitride (TaN), titanium nitride (TiN), iridium-tantalum alloy (Ir—Ta), indium-tin oxide (ITO), the like, and/or a combination thereof.

In embodiments, the first channel area 121 and the third channel area 123 may include the first type channel material, which may be an n-type channel material or a p-type channel material. On the other hand, the second channel area 122 and the fourth channel area 124 may include the second type channel material, which may be different from the first type channel material. An n-type channel material may include indium tin oxide (ITO), indium gallium zinc oxide (IGZO), indium zinc oxide (IZO), aluminum-doped zinc oxide (AZO), amorphous silicon, zinc oxide, amorphous germanium, polysilicon, poly germanium, or poly-III-V like InAs. On the other hand, a p-type channel material may include amorphous silicon, zinc oxide, amorphous germanium, polysilicon, poly germanium, poly-III-V like InAs, copper oxide (CuO), or tin oxide (SnO). The first channel area 121, the third channel area 123, the second channel area 122, and the fourth channel area 124 may have a thickness in a range of about 10 nm to about 100 nm.

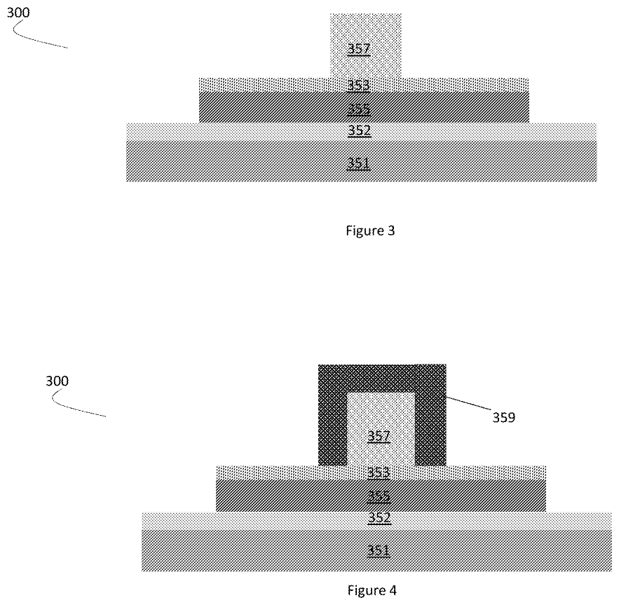

FIG. 2 illustrates a process 200 for forming a semiconductor device including two inverters at the BEOL above a substrate and multiple gate electrodes, in accordance with some embodiments. In embodiments, the process 200 may be applied to form the semiconductor device 100 including the inverter 110 and the inverter 130, as shown in FIG. 1. More details of various stages of an application of the process 200 to form a semiconductor device 300 including two inverters at the BEOL may be shown in FIGS. 3-10.

At block 201, the process 200 may include forming a backbone area above a gate electrode, wherein the gate electrode is above a substrate. For example, as shown in FIG. 3, the process 200 may be applied to form a backbone area 357 above a gate electrode 355, where the gate electrode 355 may be above a substrate 351. In embodiments, the gate electrode 355 may be above an ILD layer 352 that is above the substrate 351. A gate dielectric layer 353 may be above the gate electrode 355 and below the backbone area 357.

At block 203, the process 200 may include forming a continuous fin of a first type conformally covering the backbone area, wherein the continuous fin of the first type includes a first type channel material. For example, as shown in FIG. 4, the process 200 may be applied to form a continuous fin of a first type 359 conformally covering the backbone area 357, wherein the continuous fin of the first type 359 may include a first type channel material.

At block 205, the process 200 may include forming an oxide area conformally covering the continuous fin of the first type. For example, as shown in FIG. 5, the process 200 may be applied to form an oxide area 361 conformally covering the continuous fin of the first type 359.

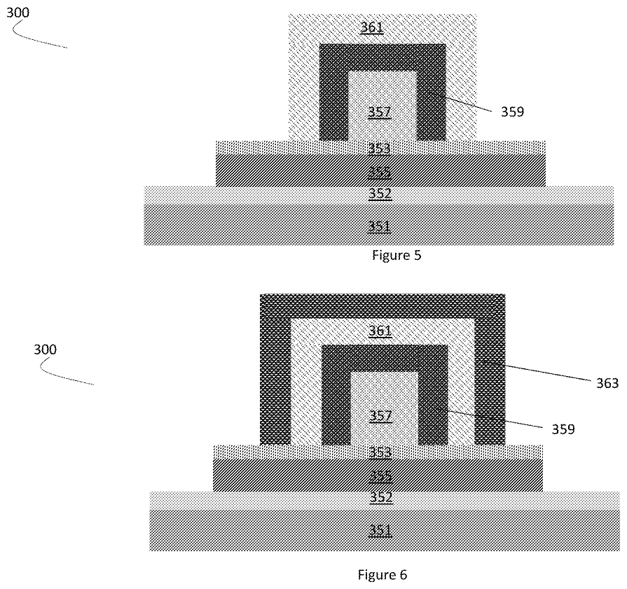

At block 207, the process 200 may include forming a continuous fin of a second type conformally covering the oxide area, wherein the continuous fin of the second type includes a second type channel material. For example, as shown in FIG. 6, the process 200 may be applied to form a continuous fin of a second type 363 conformally covering the oxide area 361, wherein the continuous fin of the second type 363 may include a second type channel material.

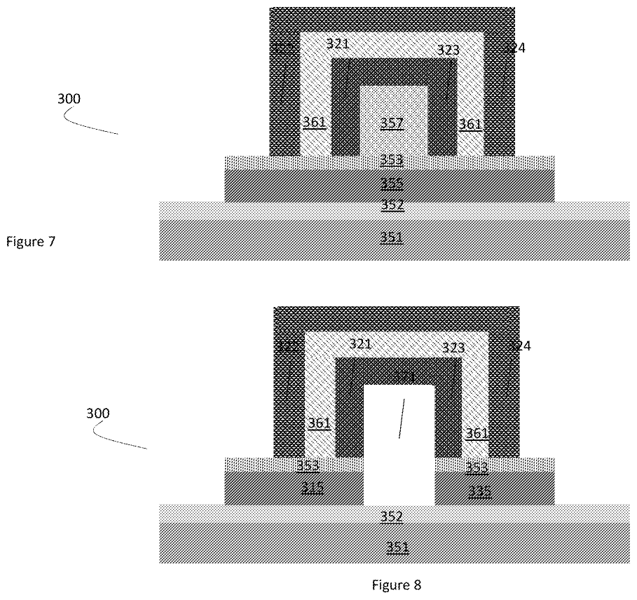

At block 209, the process 200 may include removing a top part of the continuous fin of the second type, a top part of the oxide area, a top part of the continuous fin of the first type, to expose the backbone area, wherein the continuous fin of the first type becomes a first fin of the first type and a second fin of the first type disconnected from each other, and the continuous fin of the second type becomes a first fin of the second type and a second fin of the second type disconnected from each other. For example, as shown in FIG. 7, the process 200 may be applied to remove a top part of the continuous fin of the second type 363, a top part of the oxide area 361, a top part of the continuous fin of the first type 359, to expose the backbone area 357, wherein the continuous fin of the first type 361 may become a first fin of the first type 321 and a second fin of the first type 323 disconnected from each other, and the continuous fin of the second type 363 may become a first fin of the second type 322 and a second fin of the second type 324 disconnected from each other.

At block 211, the process 200 may include removing the backbone area and a part of the gate electrode to have a gap, wherein the gate electrode becomes a first gate electrode and a second gate electrode disconnected from each other. For example, as shown in FIG. 8, the process 200 may be applied to remove the backbone area 357 and a part of the gate electrode 355 to have a gap 371, wherein the gate electrode 355 may become a first gate electrode 315 and a second gate electrode 335 disconnected from each other.

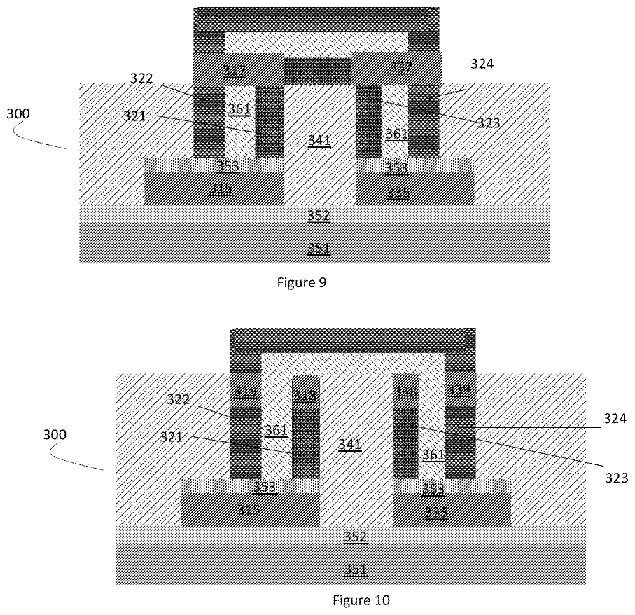

At block 213, the process 200 may include filling the gap by a dielectric material to form a spacer. At block 215, the process 200 may include forming a first source-drain contact coupled to a source area of the first fin of the first type and a drain area of the first fin of the second type, a second source-drain contact coupled to a source area of the second fin of the first type and a drain area of the second fin of the second type. For example, as shown in FIG. 9, the process 200 may be applied to fill the gap 371 by a dielectric material to form a spacer 341. In addition, the process 200 may be applied to form a first source-drain contact 317 coupled to a source area of the first fin of the first type 321 and a drain area of the first fin of the second type 322. The process 200 may be applied to form a second source-drain contact 337 coupled to a source area of the second fin of the first type 323 and a drain area of the second fin of the second type 324.

At block 217, the process 200 may include forming a drain contact coupled to a drain area of the first fin of the first type, a source contact coupled to a source area of the first fin of the second type, a drain contact coupled to a drain area of the second fin of the first type, and a source contact coupled to a source area of the second fin of the second type. For example, as shown in FIG. 10, the process 200 may be applied to form a drain contact 318 coupled to a drain area of the first fin of the first type 321, a source contact 319 coupled to a source area of the first fin of the second type 322, a drain contact 338 coupled to a drain area of the second fin of the first type 323, and a source contact 339 coupled to a source area of the second fin of the second type 324.

In addition, the process 200 may include other operations. For example, the process 200 may include forming a gate dielectric layer 353 above the gate electrode 355 before forming the backbone area 357. In addition, the removing the backbone area 357 and a part of the gate electrode 355 may further include removing a part of the gate dielectric layer 353 to have the gap 371. The gate dielectric layer 353 may include silicon and oxygen, silicon and nitrogen, yttrium and oxygen, silicon, oxygen, and nitrogen, aluminum and oxygen, hafnium and oxygen, tantalum and oxygen, or titanium and oxygen.

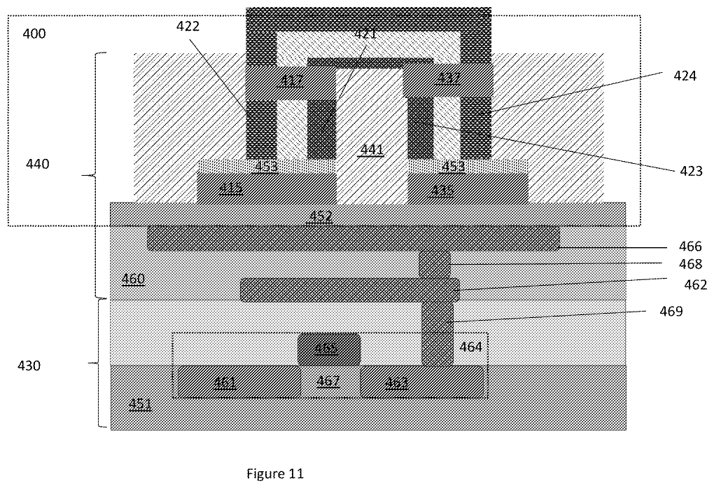

FIG. 11 schematically illustrates a diagram of a semiconductor device 400 including two inverters at the BEOL above a substrate 451 and multiple gate electrodes, in accordance with some embodiments. The semiconductor device 400 may be an example of the semiconductor device 100 in FIG. 1, or an example of the semiconductor device 300 in FIGS. 3-10. Various layers in the semiconductor device 400 may be similar to corresponding layers in the semiconductor device 100 in FIG. 1.

In embodiments, the semiconductor device 400 may include the substrate 451, and an ILD layer 452 above the substrate 451. A gate electrode 415 and a gate electrode 435 may be above the ILD layer 452 and the substrate 451, where the gate electrode 415 and the gate electrode 435 may be separated by a spacer 441. A gate dielectric layer 453 may be above the gate electrode 415 and the gate electrode 435. A first channel area 421 and a second channel area 422 may be above the gate electrode 415 and the gate dielectric layer 453, where the first channel area 421 may include a first type channel material, and the second channel area 422 may include a second type channel material. A third channel area 423 and a fourth channel area 424 may be above the gate electrode 435 and the gate dielectric layer 453, where the third channel area 423 may include the first type channel material, and the fourth channel area 424 may include the second type channel material. The third channel area 423 may be separated from the first channel area 421 by the spacer 441. A first source-drain contact 417 may be coupled to a source area of the first channel area 421 and a drain area of the second channel area 422. A second source-drain contact 437 may be coupled to a source area of the third channel area 423 and a drain area of the fourth channel area 424. Other contacts, e.g., drain contacts or source contacts coupled to the channel areas, may be formed, not shown.

In embodiments, the semiconductor device 400 may be formed at the BEOL 440. In addition to the semiconductor device 400, the BEOL 440 may further include a dielectric layer 460, where one or more vias, e.g., a via 468, may be connected to one or more interconnect, e.g., an interconnect 466, and an interconnect 462 within the dielectric layer 460. In embodiments, the interconnect 466 and the interconnect 462 may be of different metal layers at the BEOL 440. The dielectric layer 460 is shown for example only. Although not shown by FIG. 11, in various embodiments there may be multiple dielectric layers included in the BEOL 440.

In embodiments, the BEOL 440 may be formed on the FEOL 430. The FEOL 430 may include the substrate 451. In addition, the FEOL 430 may include other devices, e.g., a transistor 464. In embodiments, the transistor 464 may be a FEOL transistor, including a source 461, a drain 463, and a gate 465, with a channel 467 between the source 461 and the drain 463 under the gate 465. Furthermore, the transistor 464 may be coupled to interconnects, e.g., the interconnect 462, through a via 469.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

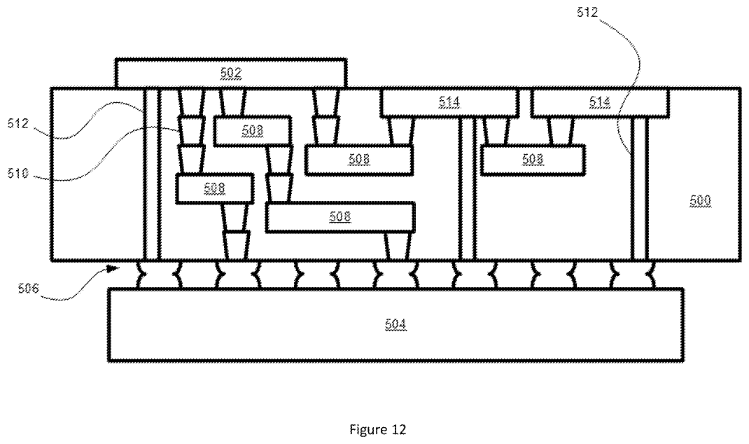

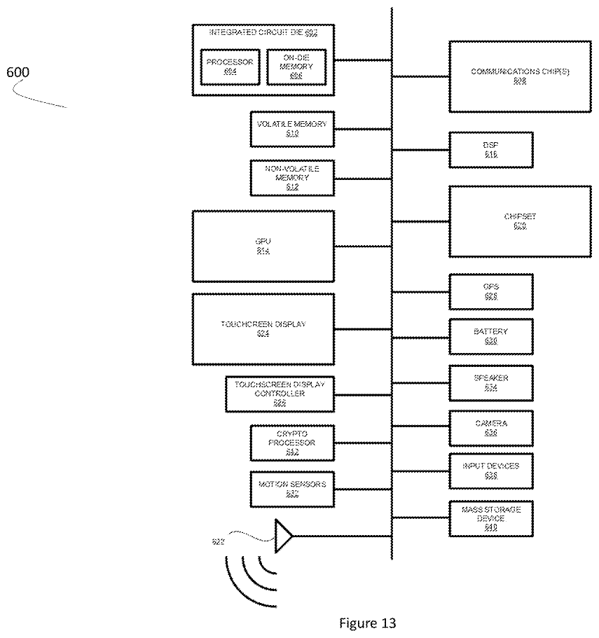

FIG. 12 illustrates an interposer 500 that includes one or more embodiments of the disclosure. The interposer 500 is an intervening substrate used to bridge a first substrate 502 to a second substrate 504. The first substrate 502 may be, for instance, a substrate support for a semiconductor device, e.g., the semiconductor device 100 shown in FIG. 1 or the semiconductor device 300 shown in FIGS. 3-10. The second substrate 504 may be, for instance, a memory module, a computer motherboard, or another integrated circuit die. Generally, the purpose of an interposer 500 is to spread a connection to a wider pitch or to reroute a connection to a different connection. For example, an interposer 500 may couple an integrated circuit die to a ball grid array (BGA) 506 that can subsequently be coupled to the second substrate 504. In some embodiments, the first and second substrates 502/504 are attached to opposing sides of the interposer 500. In other embodiments, the first and second substrates 502/504 are attached to the same side of the interposer 500. And in further embodiments, three or more substrates are interconnected by way of the interposer 500.

The interposer 500 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 508 and vias 510, including but not limited to through-silicon vias (TSVs) 512. The interposer 500 may further include embedded devices 514, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 500.

In accordance with embodiments of the disclosure, apparatuses or processes disclosed herein may be used in the fabrication of interposer 500.

FIG. 13 illustrates a computing device 600 in accordance with one embodiment of the disclosure. The computing device 600 may include a number of components. In one embodiment, these components are attached to one or more motherboards. In an alternate embodiment, some or all of these components are fabricated onto a single system-on-a-chip (SoC) die, such as a SoC used for mobile devices. The components in the computing device 600 include, but are not limited to, an integrated circuit die 602 and at least one communications logic unit 608. In some implementations the communications logic unit 608 is fabricated within the integrated circuit die 602 while in other implementations the communications logic unit 608 is fabricated in a separate integrated circuit chip that may be bonded to a substrate or motherboard that is shared with or electronically coupled to the integrated circuit die 602. The integrated circuit die 602 may include a processor 604 as well as on-die memory 606, often used as cache memory, which can be provided by technologies such as embedded DRAM (eDRAM), or SRAM. For example, the on-die memory 606 may include the semiconductor device 100 shown in FIG. 1, the semiconductor device 300 shown in FIGS. 3-10, or a semiconductor device formed according to the process 200 shown in FIG. 2.

In embodiments, the computing device 600 may include a display or a touchscreen display 624, and a touchscreen display controller 626. A display or the touchscreen display 624 may include a FPD, an AMOLED display, a TFT LCD, a micro light-emitting diode (μLED) display, or others. For example, the touchscreen display 624 may include the semiconductor device 100 shown in FIG. 1, the semiconductor device 300 shown in FIGS. 3-10, or a semiconductor device formed according to the process 200 shown in FIG. 2.

Computing device 600 may include other components that may or may not be physically and electrically coupled to the motherboard or fabricated within a SoC die. These other components include, but are not limited to, volatile memory 610 (e.g., dynamic random access memory (DRAM), non-volatile memory 612 (e.g., ROM or flash memory), a graphics processing unit 614 (GPU), a digital signal processor (DSP) 616, a crypto processor 642 (e.g., a specialized processor that executes cryptographic algorithms within hardware), a chipset 620, at least one antenna 622 (in some implementations two or more antenna may be used), a battery 630 or other power source, a power amplifier (not shown), a voltage regulator (not shown), a global positioning system (GPS) device 628, a compass, a motion coprocessor or sensors 632 (that may include an accelerometer, a gyroscope, and a compass), a microphone (not shown), a speaker 634, a camera 636, user input devices 638 (such as a keyboard, mouse, stylus, and touchpad), and a mass storage device 640 (such as hard disk drive, compact disk (CD), digital versatile disk (DVD), and so forth). The computing device 600 may incorporate further transmission, telecommunication, or radio functionality not already described herein. In some implementations, the computing device 600 includes a radio that is used to communicate over a distance by modulating and radiating electromagnetic waves in air or space. In further implementations, the computing device 600 includes a transmitter and a receiver (or a transceiver) that is used to communicate over a distance by modulating and radiating electromagnetic waves in air or space.

The communications logic unit 608 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communications logic unit 608 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Infrared (IR), Near Field Communication (NFC), Bluetooth, derivatives thereof, as well as any other wireless protocols that are designated as 3G, 4G, 5G, and beyond. The computing device 600 may include a plurality of communications logic units 608. For instance, a first communications logic unit 608 may be dedicated to shorter range wireless communications such as Wi-Fi, NFC, and Bluetooth and a second communications logic unit 608 may be dedicated to longer range wireless communications such as GPS, EDGE, GPRS, CDMA, WiMAX, LTE, Ev-DO, and others.

The processor 604 of the computing device 600 includes one or more devices, such as transistors. The term “processor” may refer to any device or portion of a device that processes electronic data from registers and/or memory to transform that electronic data into other electronic data that may be stored in registers and/or memory. The communications logic unit 608 may also include one or more devices, such as transistors.

In further embodiments, another component housed within the computing device 600 may contain one or more devices, such as DRAM, that are formed in accordance with implementations of the current disclosure, e.g., the semiconductor device 100 shown in FIG. 1, the semiconductor device 300 shown in FIGS. 3-10, or a semiconductor device formed according to the process 200 shown in FIG. 2.

In various embodiments, the computing device 600 may be a laptop computer, a netbook computer, a notebook computer, an ultrabook computer, a smartphone, a dumbphone, a tablet, a tablet/laptop hybrid, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

Some non-limiting Examples are provided below.

Example 1 may include a semiconductor device, comprising: a substrate; a first gate electrode and a second gate electrode above the substrate, wherein the first gate electrode and the second gate electrode are separated by a spacer; a first channel area and a second channel area above the first gate electrode, wherein the first channel area includes a first type channel material, and the second channel area includes a second type channel material; a third channel area and a fourth channel area above the second gate electrode, wherein the third channel area includes the first type channel material, and the fourth channel area includes the second type channel material, the third channel area is separated from the first channel area by the spacer; a first source-drain contact coupled to a source area of the first channel area and a drain area of the second channel area, a second source-drain contact coupled to a source area of the third channel area and a drain area of the fourth channel area; and a drain contact coupled to a drain area of the first channel area, a source contact coupled to a source area of the second channel area, a drain contact coupled to a drain area of the third channel area, and a source contact coupled to a source area of the fourth channel area.

Example 2 may include the semiconductor device of example 1 and/or some other examples herein, further comprising: an interlayer dielectric (ILD) layer above the substrate and below the first gate electrode and the second gate electrode.

Example 3 may include the semiconductor device of example 1 and/or some other examples herein, further comprising: a gate dielectric layer above the first gate electrode and the second gate electrode, and below the first channel area, the second channel area, the third channel area, and the fourth channel area, wherein the gate dielectric layer includes silicon and oxygen, silicon and nitrogen, yttrium and oxygen, silicon, oxygen, and nitrogen, aluminum and oxygen, hafnium and oxygen, tantalum and oxygen, or titanium and oxygen.

Example 4 may include the semiconductor device of any one of examples 1-3 and/or some other examples herein, wherein the first type channel material is an n-type channel material and includes indium tin oxide (ITO), indium gallium zinc oxide (IGZO), indium zinc oxide (IZO), aluminum-doped zinc oxide (AZO), amorphous silicon, zinc oxide, amorphous germanium, polysilicon, poly germanium, or poly-III-V like InAs.

Example 5 may include the semiconductor device of any one of examples 1-3 and/or some other examples herein, wherein the first type channel material is a p-type channel material and includes amorphous silicon, zinc oxide, amorphous germanium, polysilicon, poly germanium, poly-III-V like InAs, copper oxide (CuO), or tin oxide (SnO).

Example 6 may include the semiconductor device of any one of examples 1-3 and/or some other examples herein, wherein the spacer includes silicon oxide (SiO), silicon nitride (SiN), O₃-tetraethylorthosilicate (TEOS), O₃-hexamethyldisiloxane (HMDS), or plasma-TEOS oxide.

Example 7 may include the semiconductor device of any one of examples 1-3 and/or some other examples herein, wherein the first gate electrode or the second gate electrode includes titanium (Ti), molybdenum (Mo), gold (Au), platinum (Pt), aluminum (Al), nickel (Ni), copper (Cu), chromium (Cr), or an alloy of Ti, Mo, Au, Pt, Al Ni, Cu, Cr, TiAlN, HfAlN, or InAlO.

Example 8 may include the semiconductor device of any one of examples 1-3 and/or some other examples herein, wherein the substrate includes a silicon substrate, a glass substrate, a metal substrate, or a plastic substrate.

Example 9 may include the semiconductor device of any one of examples 1-3 and/or some other examples herein, wherein the first gate electrode and the second gate electrode are above an interconnect, and the interconnect is above the substrate.

Example 10 may include a computing device comprising: a processor; a memory device coupled to the processor, wherein the processor or the memory device includes a first inverter and a second inverter, and the first inverter and the second inverter include: a substrate; a first gate electrode and a second gate electrode above the substrate, wherein the first gate electrode and the second gate electrode are separated by a spacer; a first channel area and a second channel area above the first gate electrode, wherein the first channel area includes a first type channel material, and the second channel area includes a second type channel material; a third channel area and a fourth channel area above the second gate electrode, wherein the third channel area includes the first type channel material, and the fourth channel area includes the second type channel material, the third channel area is separated from the first channel area by the spacer; a first source-drain contact coupled to a source area of the first channel area and a drain area of the second channel area, a second source-drain contact coupled to a source area of the third channel area and a drain area of the fourth channel area, wherein: the first inverter includes the first gate electrode, the first channel area, the second channel area, and the first source-drain contact coupled to the source area of the first channel area and the drain area of the second channel area; and the second inverter includes the second gate electrode, the third channel area, the fourth channel area, and the second source-drain contact coupled to the source area of the third channel area and the drain area of the fourth channel area.

Example 11 may include the computing device of example 10 and/or some other examples herein, further comprising: an interlayer dielectric (ILD) layer above the substrate and below the first gate electrode and the second gate electrode.

Example 12 may include the computing device of example 10 and/or some other examples herein, further comprising: a gate dielectric layer above the first gate electrode and the second gate electrode, and below the first channel area, the second channel area, the third channel area, and the fourth channel area, wherein the gate dielectric layer includes silicon and oxygen, silicon and nitrogen, yttrium and oxygen, silicon, oxygen, and nitrogen, aluminum and oxygen, hafnium and oxygen, tantalum and oxygen, or titanium and oxygen.

Example 13 may include the computing device of any one of examples 10-12 and/or some other examples herein, wherein the first type channel material is an n-type channel material and includes indium tin oxide (ITO), indium gallium zinc oxide (IGZO), indium zinc oxide (IZO), aluminum-doped zinc oxide (AZO), amorphous silicon, zinc oxide, amorphous germanium, polysilicon, poly germanium, or poly-III-V like InAs.

Example 14 may include the computing device of any one of examples 10-12 and/or some other examples herein, wherein the first type channel material is a p-type channel material and includes amorphous silicon, zinc oxide, amorphous germanium, polysilicon, poly germanium, poly-III-V like InAs, copper oxide (CuO), or tin oxide (SnO).

Example 15 may include the computing device of any one of examples 10-12 and/or some other examples herein, wherein the first gate electrode or the second gate electrode includes titanium (Ti), molybdenum (Mo), gold (Au), platinum (Pt), aluminum (Al), nickel (Ni), copper (Cu), chromium (Cr), or an alloy of Ti, Mo, Au, Pt, Al Ni, Cu, Cr, TiAlN, HfAlN, or InAlO.

Example 16 may include the computing device of any one of examples 10-12 and/or some other examples herein, wherein the spacer includes silicon oxide (SiO), silicon nitride (SiN), O₃-tetraethylorthosilicate (TEOS), O₃-hexamethyldisiloxane (HMDS), or plasma-TEOS oxide.

Example 17 may include the computing device of any one of examples 10-12 and/or some other examples herein, wherein the computing device is a wearable device or a mobile computing device, the wearable device or the mobile computing device including one or more of an antenna, a touchscreen controller, a battery, an audio codec, a video codec, a power amplifier, a global positioning system (GPS) device, a compass, a Geiger counter, an accelerometer, a gyroscope, a speaker, or a camera coupled with the circuit board.

Example 18 may include a method for forming a semiconductor device, the method comprising: forming a backbone area above a gate electrode, wherein the gate electrode is above a substrate; forming a continuous fin of a first type conformally covering the backbone area, wherein the continuous fin of the first type includes a first type channel material; forming an oxide area conformally covering the continuous fin of the first type; forming a continuous fin of a second type conformally covering the oxide area, wherein the continuous fin of the second type includes a second type channel material; removing a top part of the continuous fin of the second type, a top part of the oxide area, a top part of the continuous fin of the first type, to expose the backbone area, wherein the continuous fin of the first type becomes a first fin of the first type and a second fin of the first type disconnected from each other, and the continuous fin of the second type becomes a first fin of the second type and a second fin of the second type disconnected from each other; removing the backbone area and a part of the gate electrode to have a gap, wherein the gate electrode becomes a first gate electrode and a second gate electrode disconnected from each other; and filling the gap by a dielectric material to form a spacer.

Example 19 may include the method of example 18 and/or some other examples herein, further comprising: forming a first source-drain contact coupled to a source area of the first fin of the first type and a drain area of the first fin of the second type, a second source-drain contact coupled to a source area of the second fin of the first type and a drain area of the second fin of the second type; and forming a drain contact coupled to a drain area of the first fin of the first type, a source contact coupled to a source area of the first fin of the second type, a drain contact coupled to a drain area of the second fin of the first type, and a source contact coupled to a source area of the second fin of the second type.

Example 20 may include the method of example 18 and/or some other examples herein, further comprising: forming a gate dielectric layer above the gate electrode before forming the backbone area, wherein the removing the backbone area and the part of the gate electrode further includes removing a part of the gate dielectric layer to have the gap, the gate electrode becomes the first gate electrode and the second gate electrode, and the gate dielectric layer includes silicon and oxygen, silicon and nitrogen, yttrium and oxygen, silicon, oxygen, and nitrogen, aluminum and oxygen, hafnium and oxygen, tantalum and oxygen, or titanium and oxygen.

Example 21 may include the method of any one of examples 18-20 and/or some other examples herein, wherein the first type channel material is an n-type material and includes indium tin oxide (ITO), indium gallium zinc oxide (IGZO), indium zinc oxide (IZO), aluminum-doped zinc oxide (AZO), amorphous silicon, zinc oxide, amorphous germanium, polysilicon, poly germanium, or poly-II-V like InAs.

Example 22 may include the method of any one of examples 18-20 and/or some other examples herein, wherein the first type channel material is a p-type material and includes amorphous silicon, zinc oxide, amorphous germanium, polysilicon, poly germanium, poly-III-V like InAs, copper oxide (CuO), or tin oxide (SnO).

Example 23 may include the method of any one of examples 18-20 and/or some other examples herein, wherein the spacer includes silicon oxide (SiO), silicon nitride (SiN), O₃-tetraethylorthosilicate (TEOS), O₃-hexamethyldisiloxane (HMDS), or plasma-TEOS oxide.

Example 24 may include the method of any one of examples 18-20 and/or some other examples herein, wherein the first gate electrode or the second gate electrode includes titanium (Ti), molybdenum (Mo), gold (Au), platinum (Pt), aluminum (Al), nickel (Ni), copper (Cu), chromium (Cr), or an alloy of Ti, Mo, Au, Pt, Al Ni, Cu, Cr, TiAlN, HfAlN, or InAlO.

Example 25 may include the method of any one of examples 18-20 and/or some other examples herein, wherein the substrate includes a silicon substrate, a glass substrate, a metal substrate, or a plastic substrate.

Example 26 may include one or more computer-readable media having instructions for a computer device to form a semiconductor device, upon execution of the instructions by one or more processors, to perform the method of any one of examples 18-25.

Example 27 may include an apparatus for forming a semiconductor device, comprising: means for forming a backbone area above a gate electrode, wherein the gate electrode is above a substrate; means for forming a continuous fin of a first type conformally covering the backbone area, wherein the continuous fin of the first type includes a first type channel material; means for forming an oxide area conformally covering the continuous fin of the first type; means for forming a continuous fin of a second type conformally covering the oxide area, wherein the continuous fin of the second type includes a second type channel material; means for removing a top part of the continuous fin of the second type, a top part of the oxide area, a top part of the continuous fin of the first type, to expose the backbone area, wherein the continuous fin of the first type becomes a first fin of the first type and a second fin of the first type disconnected from each other, and the continuous fin of the second type becomes a first fin of the second type and a second fin of the second type disconnected from each other; means for removing the backbone area and a part of the gate electrode to have a gap, wherein the gate electrode becomes a first gate electrode and a second gate electrode disconnected from each other; and means for filling the gap by a dielectric material to form a spacer.

Example 28 may include the apparatus of example 27 and/or some other examples herein, further comprising: means for forming a first source-drain contact coupled to a source area of the first fin of the first type and a drain area of the first fin of the second type, a second source-drain contact coupled to a source area of the second fin of the first type and a drain area of the second fin of the second type; and means for forming a drain contact coupled to a drain area of the first fin of the first type, a source contact coupled to a source area of the first fin of the second type, a drain contact coupled to a drain area of the second fin of the first type, and a source contact coupled to a source area of the second fin of the second type.

Example 29 may include the apparatus of example 27 and/or some other examples herein, further comprising: means for forming a gate dielectric layer above the gate electrode before forming the backbone area, wherein the means for removing the backbone area and the part of the gate electrode further includes means for removing a part of the gate dielectric layer to have the gap, the gate electrode becomes the first gate electrode and the second gate electrode, and the gate dielectric layer includes silicon and oxygen, silicon and nitrogen, yttrium and oxygen, silicon, oxygen, and nitrogen, aluminum and oxygen, hafnium and oxygen, tantalum and oxygen, or titanium and oxygen.

Example 30 may include the apparatus of any one of examples 27-29 and/or some other examples herein, wherein the first type channel material is an n-type material and includes indium tin oxide (ITO), indium gallium zinc oxide (IGZO), indium zinc oxide (IZO), aluminum-doped zinc oxide (AZO), amorphous silicon, zinc oxide, amorphous germanium, polysilicon, poly germanium, or poly-III-V like InAs.

Example 31 may include the apparatus of any one of examples 27-29 and/or some other examples herein, wherein the first type channel material is a p-type material and includes amorphous silicon, zinc oxide, amorphous germanium, polysilicon, poly germanium, poly-III-V like InAs, copper oxide (CuO), or tin oxide (SnO).

Example 32 may include the apparatus of any one of examples 27-29 and/or some other examples herein, wherein the spacer includes silicon oxide (SiO), silicon nitride (SiN), O₃-tetraethylorthosilicate (TEOS), O₃-hexamethyldisiloxane (HMDS), or plasma-TEOS oxide.

Example 33 may include the apparatus of any one of examples 27-29 and/or some other examples herein, wherein the first gate electrode or the second gate electrode includes titanium (Ti), molybdenum (Mo), gold (Au), platinum (Pt), aluminum (Al), nickel (Ni), copper (Cu), chromium (Cr), or an alloy of Ti, Mo, Au, Pt, Al Ni, Cu, Cr, TiAlN, HfAlN, or InAlO.

Example 34 may include the apparatus of any one of examples 27-29 and/or some other examples herein, wherein the substrate includes a silicon substrate, a glass substrate, a metal substrate, or a plastic substrate.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated implementations, including what is described in the Abstract, is not intended to be exhaustive or to limit the embodiments of the present disclosure to the precise forms disclosed. While specific implementations and examples are described herein for illustrative purposes, various equivalent modifications are possible within the scope of the present disclosure, as those skilled in the relevant art will recognize.

These modifications may be made to embodiments of the present disclosure in light of the above detailed description. The terms used in the following claims should not be construed to limit various embodiments of the present disclosure to the specific implementations disclosed in the specification and the claims. Rather, the scope is to be determined entirely by the following claims, which are to be construed in accordance with established doctrines of claim interpretation.

1. A semiconductor device, comprising:
a substrate;
a first gate electrode and a second gate electrode above the substrate, wherein the first gate electrode and the second gate electrode are separated by a spacer;
a first channel area and a second channel area above the first gate electrode, wherein the first channel area includes a first type channel material, and the second channel area includes a second type channel material;
a third channel area and a fourth channel area above the second gate electrode, wherein the third channel area includes the first type channel material, and the fourth channel area includes the second type channel material, the third channel area is separated from the first channel area by the spacer;
a first source-drain contact coupled to a source area of the first channel area and a drain area of the second channel area, a second source-drain contact coupled to a source area of the third channel area and a drain area of the fourth channel area; and
a drain contact coupled to a drain area of the first channel area, a source contact coupled to a source area of the second channel area, a drain contact coupled to a drain area of the third channel area, and a source contact coupled to a source area of the fourth channel area.

2. The semiconductor device of claim 1, further comprising:
an interlayer dielectric (ILD) layer above the substrate and below the first gate electrode and the second gate electrode.

3. The semiconductor device of claim 1, further comprising:
a gate dielectric layer above the first gate electrode and the second gate electrode, and below the first channel area, the second channel area, the third channel area, and the fourth channel area, wherein the gate dielectric layer includes silicon and oxygen, silicon and nitrogen, yttrium and oxygen, silicon, oxygen, and nitrogen, aluminum and oxygen, hafnium and oxygen, tantalum and oxygen, or titanium and oxygen.

4. The semiconductor device of claim 1, wherein the first type channel material is an n-type channel material and includes indium tin oxide (ITO), indium gallium zinc oxide (IGZO), indium zinc oxide (IZO), aluminum-doped zinc oxide (AZO), amorphous silicon, zinc oxide, amorphous germanium, polysilicon, poly germanium, or poly-III-V like InAs.

5. The semiconductor device of claim 1, wherein the first type channel material is a p-type channel material and includes amorphous silicon, zinc oxide, amorphous germanium, polysilicon, poly germanium, poly-III-V like InAs, copper oxide (CuO), or tin oxide (SnO).

6. The semiconductor device of claim 1, wherein the spacer includes silicon oxide (SiO), silicon nitride (SiN), O₃-tetraethylorthosilicate (TEOS), O₃-hexamethyldisiloxane (HMDS), or plasma-TEOS oxide.

7. The semiconductor device of claim 1,
wherein the first gate electrode or the second gate electrode includes titanium (Ti), molybdenum (Mo), gold (Au), platinum (Pt), aluminum (Al), nickel (Ni), copper (Cu), chromium (Cr), or an alloy of Ti, Mo, Au, Pt, Al Ni, Cu, Cr, TiAlN, HfAlN, or InAlO.

8. The semiconductor device of claim 1, wherein the substrate includes a silicon substrate, a glass substrate, a metal substrate, or a plastic substrate.

9. The semiconductor device of claim 1, wherein the first gate electrode and the second gate electrode are above an interconnect, and the interconnect is above the substrate.

10. A computing device comprising:
a processor;
a memory device coupled to the processor, wherein the processor or the memory device includes a first inverter and a second inverter, and the first inverter and the second inverter include:
a substrate;
a first gate electrode and a second gate electrode above the substrate, wherein the first gate electrode and the second gate electrode are separated by a spacer;
a first channel area and a second channel area above the first gate electrode, wherein the first channel area includes a first type channel material, and the second channel area includes a second type channel material;
a third channel area and a fourth channel area above the second gate electrode, wherein the third channel area includes the first type channel material, and the fourth channel area includes the second type channel material, the third channel area is separated from the first channel area by the spacer;
a first source-drain contact coupled to a source area of the first channel area and a drain area of the second channel area, a second source-drain contact coupled to a source area of the third channel area and a drain area of the fourth channel area, wherein:
the first inverter includes the first gate electrode, the first channel area, the second channel area, and the first source-drain contact coupled to the source area of the first channel area and the drain area of the second channel area; and
the second inverter includes the second gate electrode, the third channel area, the fourth channel area, and the second source-drain contact coupled to the source area of the third channel area and the drain area of the fourth channel area.

11. The computing device of claim 10, further comprising:
an interlayer dielectric (ILD) layer above the substrate and below the first gate electrode and the second gate electrode.

12. The computing device of claim 10, further comprising:
a gate dielectric layer above the first gate electrode and the second gate electrode, and below the first channel area, the second channel area, the third channel area, and the fourth channel area, wherein the gate dielectric layer includes silicon and oxygen, silicon and nitrogen, yttrium and oxygen, silicon, oxygen, and nitrogen, aluminum and oxygen, hafnium and oxygen, tantalum and oxygen, or titanium and oxygen.

13. The computing device of claim 10, wherein the first type channel material is an n-type channel material and includes indium tin oxide (ITO), indium gallium zinc oxide (IGZO), indium zinc oxide (IZO), aluminum-doped zinc oxide (AZO), amorphous silicon, zinc oxide, amorphous germanium, polysilicon, poly germanium, or poly-III-V like InAs.

14. The computing device of claim 10, wherein the first type channel material is a p-type channel material and includes amorphous silicon, zinc oxide, amorphous germanium, polysilicon, poly germanium, poly-III-V like InAs, copper oxide (CuO), or tin oxide (SnO).

15. The computing device of claim 10, wherein the first gate electrode or the second gate electrode includes titanium (Ti), molybdenum (Mo), gold (Au), platinum (Pt), aluminum (Al), nickel (Ni), copper (Cu), chromium (Cr), or an alloy of Ti, Mo, Au, Pt, Al Ni, Cu, Cr, TiAlN, HfAlN, or InAlO.

16. The semiconductor device of claim 10, wherein the spacer includes silicon oxide (SiO), silicon nitride (SiN), O₃-tetraethylorthosilicate (TEOS), O₃-hexamethyldisiloxane (HMDS), or plasma-TEOS oxide.

17. The computing device of claim 10, wherein the computing device is a wearable device or a mobile computing device, the wearable device or the mobile computing device including one or more of an antenna, a touchscreen controller, a battery, an audio codec, a video codec, a power amplifier, a global positioning system (GPS) device, a compass, a Geiger counter, an accelerometer, a gyroscope, a speaker, or a camera coupled with the circuit board.

18. A method for forming a semiconductor device, the method comprising:
forming a backbone area above a gate electrode, wherein the gate electrode is above a substrate;
forming a continuous fin of a first type conformally covering the backbone area, wherein the continuous fin of the first type includes a first type channel material;
forming an oxide area conformally covering the continuous fin of the first type;
forming a continuous fin of a second type conformally covering the oxide area, wherein the continuous fin of the second type includes a second type channel material;
removing a top part of the continuous fin of the second type, a top part of the oxide area, a top part of the continuous fin of the first type, to expose the backbone area, wherein the continuous fin of the first type becomes a first fin of the first type and a second fin of the first type disconnected from each other, and the continuous fin of the second type becomes a first fin of the second type and a second fin of the second type disconnected from each other;
removing the backbone area and a part of the gate electrode to have a gap, wherein the gate electrode becomes a first gate electrode and a second gate electrode disconnected from each other; and
filling the gap by a dielectric material to form a spacer.

19. The method of claim 18, further comprising:
forming a first source-drain contact coupled to a source area of the first fin of the first type and a drain area of the first fin of the second type, a second source-drain contact coupled to a source area of the second fin of the first type and a drain area of the second fin of the second type; and
forming a drain contact coupled to a drain area of the first fin of the first type, a source contact coupled to a source area of the first fin of the second type, a drain contact coupled to a drain area of the second fin of the first type, and a source contact coupled to a source area of the second fin of the second type.

20. The method of claim 18, further comprising:
forming a gate dielectric layer above the gate electrode before forming the backbone area, wherein the removing the backbone area and the part of the gate electrode further includes removing a part of the gate dielectric layer to have the gap, the gate electrode becomes the first gate electrode and the second gate electrode, and the gate dielectric layer includes silicon and oxygen, silicon and nitrogen, yttrium and oxygen, silicon, oxygen, and nitrogen, aluminum and oxygen, hafnium and oxygen, tantalum and oxygen, or titanium and oxygen.

21. The method of claim 18, wherein the first type channel material is an n-type material and includes indium tin oxide (ITO), indium gallium zinc oxide (IGZO), indium zinc oxide (IZO), aluminum-doped zinc oxide (AZO), amorphous silicon, zinc oxide, amorphous germanium, polysilicon, poly germanium, or poly-III-V like InAs.

22. The method of claim 18, wherein the first type channel material is a p-type material and includes amorphous silicon, zinc oxide, amorphous germanium, polysilicon, poly germanium, poly-III-V like InAs, copper oxide (CuO), or tin oxide (SnO).

23. The method of claim 18, wherein the spacer includes silicon oxide (SiO), silicon nitride (SiN), O₃-tetraethylorthosilicate (TEOS), O₃-hexamethyldisiloxane (HMDS), or plasma-TEOS oxide.

24. The method of claim 18, wherein the first gate electrode or the second gate electrode includes titanium (Ti), molybdenum (Mo), gold (Au), platinum (Pt), aluminum (Al), nickel (Ni), copper (Cu), chromium (Cr), or an alloy of Ti, Mo, Au, Pt, Al Ni, Cu, Cr, TiAlN, HfAlN, or InAlO.

25. The method of claim 18, wherein the substrate includes a silicon substrate, a glass substrate, a metal substrate, or a plastic substrate.
